(19) United States
(12) Patent Application Publication
(10) Pub. No.: US 2002/0069824 A1
(43) Pub. Date: Jun. 13, 2002

(54) Ion implantation system having increased implanter source life

(76) Inventor: Nelson A. Dangelo, Elizaville, NY (US)

Correspondence Address: Philmore H. Colburn II, CANTOR COLBURN LLP, 55 Griffin Road South, Bloomfield, CT, 06002, US

(21) Appl. No.: 09/733,333

(22) Filed: Dec. 8, 2000

(51) Int. Cl. C23C 16/00

(52) U.S. Cl. 118/715

(57) ABSTRACT

An arc chamber of an ion implanter system comprising an electron emissive source extending into the arc chamber through a wall of electrically insulating material.

### BACKGROUND OF THE INVENTION

The present invention relates to systems for implanting preselected ions into a target. More particularly, the present invention relates to an arc chamber and filament source for generating preselected ions apparatus for ion implanting into a target wherein the implanter source has an improved utility lifetime.

In the manufacture of semiconductor devices, various regions of a semiconductor wafer maybe modified by diffusing or implanting positive or negative ions (dopants), such as boron, phosphorus, arsenic, antimony and the like, into the body of the wafer to produce regions having altered conductivity. The objective generally is to accelerate a gaseous dopant material into the silicon substrate, or, stated simply, to apply a semiconductor material into the upper layer of a silicon wafer or other substrate. As semiconductor devices evolve into smaller and smaller sizes, as in the manufacture of LSI and VLSI devices, the devices and interconnections between them become set closer and closer together. The reduction in size results in more efficient use of the wafer and increased speed of operation of the devices, but, concomitantly, reduction in size demands more precision in the placement of the dopant conductivity modifiers.

While the advent of high density circuits requires smaller feature size and closer spacing of the circuit components, diffusion techniques, which involve depositing conductivity modifying dopant ions on the surface of a wafer and driving them into the body of the wafer with heat, has inherent limitations in establishing tight control of geometries. Diffusion processes drive ions into a wafer both laterally and perpendicularly. However, ion implantation techniques drive ions into a wafer in an anisotropic manner, and, accordingly, has become the doping of choice for the manufacture of modem evolved smaller devices. The basic operation of ion implant involves a filament source emitting electrons inside an arc chamber in a state of high vacuum. These emitted electrons come off and collide with gas molecules that are introduced into the chamber. The collisions of the electrons with the gas molecules cause the gas molecules to gain or lose their electrons. The gas molecule, accordingly, has changed from neutral to being electrically charged, or ionized, and then is propelled into a target by means of high voltage electrical attraction or acceleration.

The same dopant elements that are used in diffusion processes also can be used in ion implant processes. For ion implantation gas sources of the selected dopants generally are preferred. Various types of ion implanters are known, using several types of ion sources. Generally, an ion beam of a preselected chemical species is generated by means of a current applied to an electron emissive source, within an ion arc chamber, also fitted with a power supply, ion precursor gas, feeds and controls. Generated ions are extracted through an aperture in the arc chamber by means of a potential between the chamber, which is positive, and an extraction means. Selection of the desired dopant species from the other species resulting from the ionization is accomplished in a magnetic analysis stage that separates the desired ions from unwanted ions on the basis of mass and focuses the ion beam. Upon leaving the analysis stage, the preselected ion enters an acceleration stage that ensures that the ion will have sufficient momentum to penetrate the target or substrate wafer to be implanted. The size and intensity of the generated ion beam can be tailored by system design and operating conditions.

One common type of source used commercially is known as a Freeman source. In the Freeman source (shown in FIG. 1), the filament, or cathode, is a straight rod that can be made of tungsten or tungsten alloy, or other known source material such as iridium, that is passed into an arc chamber whose walls are the anode. Another common type of ion source is known as a Bernas source. A Bernas source (shown in FIG. 2) primarily differs from a Freeman source is that the filament is in the form of a loop at one end of the arc chamber, rather than a rod-like filament, that extends into the arc chamber. (Another type of source is an incandescent heated cathode (see FIG. 3) wherein a filament is used to heat a cathode, which, in turn, emits electrons.) The arc chamber generally comprises a walled enclosure wherein one wall is fitted with an exit aperture, and another wall is furnished with means for introducing the desired gaseous ion precursors for the desired ions. The chamber typically is equipped with vacuum means, with means for heating the cathode to about 2000° K. up to about 2800° K. so that it will emit electrons, with a magnet that applies a magnetic field parallel to the filament to increase the electron path length; and with a power supply connected to the filament within the arc chamber.

As power is applied to the filament source, the source increases in temperature until it emits electrons that bombard the precursor dopant gas molecules. The molecules are broken down so that a plasma is formed containing the electrons and various positive ions. The ions are emitted from the source chamber through the exit aperture are analyzed and separated, and then are accelerated and selectively passed to the target.

As the gaseous dopant precursor materials are passed over the heated filament, the filament source decomposes the precursor materials into the desired ion for implantation as well as various other species. For example, typical precursor materials such as AsH₃ decomposes into As, H, and AsHₓ species; BF decomposes into B, BF₂, F, and other BF species.

The decomposition of the precursor material and the ionized species created by the decomposition can cause problems in the operation of the ion implanters. For example, the F (fluorine) ions produced by the ion implanter may cause a problem etching away tungsten from the source cavity, forming gaseous WF₆. The WF₆ then diffuses to and decomposes on the surface of the filament. This results in the deposition of metallic tungsten on the hot filament and the liberation of fluorine ions.

The metallic tungsten deposited on the filament causes the filament to increase in a cross-sectional area, resulting in decreased filament resistance. By affecting filament resistance, deposition of metallic tungsten on the filament may affect the power input to the ion implanter source. For best results, the power input to the source should remain constant. If the filament resistance decreases, then the filament current must increase to maintain the required constant power. Ultimately the implant power supplies cannot supply sufficient current to maintain this fixed power gas requirement, and the source must be rebuilt with a new filament.

Tungsten erosion from the filament also may result from hydrogen produced by the decomposition of arsine and phosphine. The hydrogen tends to remove tungsten from the filament, which can lead to premature source failure in the form of blown filaments.

Where the filament source extends through the arc chamber wall, it typically is insulated with electrical insulators that also serve to support the filament. The insulators are made of high temperature ceramic materials, such as alumina or boron nitride, that are engineered to withstand high temperatures and the corrosive atmosphere generated by precursor gas species such as BF₃ or SiF₄, and fragments thereof. The insulators, however, also limit the lifetime of the ion source. Even when using non-fluorinated precursor materials, tungsten sputters off of the filament, decreasing the filament's cross sectional area. The filament eventually becomes thin and will break, again resulting in the need to rebuild the source with a new filament source. This sputtered-away tungsten also causes a problem in that it will deposit on the surface of the insulators that electrically isolate the various parts of the implant source. This will cause premature insulator failure and again result in the need to rebuild the ion source. In addition, although the exact number and type of ions that are generated in the source chamber are not known with certainty, various ions generated in the chamber can react both with the graphite or molybdenum walls of the chamber and with other ions in the chamber to form reaction products that deposit on the surface of the insulator, forming a conductive coating. For example, when BF₃ is fed to the source chamber, chemical reactions with carbon from the graphite chamber walls and fluorine produce various carbon-fluoride species, such as CF and CF₂, which further react to form a fine dust that coats the insulator. Conductive compounds may also be generated from other parts of the source chamber. Even a very thin conductive coating short circuits the arc supply and interferes with the stability of the ion beam emitted from the source chamber, eventually rendering it unusable. At this point the chamber must be cleaned and the insulators and filament reconditioned or replaced. This is the most common and most frequent cause of downtime for ion implanters.

The time spent doing these source changes is a major cost-of-ownership driver for ion implanters. In some cases, such as if only GeF₄ were run on a tool, the source must be replaced every 30 hours. In another case, such as if only BF₃ were run on a tool, the source must be replaced every 30 hours. In another case, such as if only BF₃ were run on an ion implanter, the source must be changed every 36 to 48 hours. Changing the source takes a significant amount of maintenance labor and can take up to 4-6 hours of tool down-time to complete. Clearly, source changeouts represent a significant drain on money, resources, and manpower.

Various approaches have been proposed to prevent formation of these conductive coatings on the insulators. For example, changing the geometry of the electrical insulators in an arc chamber reduces formation of the coating, but this still does not greatly extend the lifetime of the unit. Other ideas include shields for the insulators to protect them from forming a conductive coating. However, the shields themselves also add instabilities to the implanter system. Another approach is a cleaning discharge operation to attempt to etch the conductive coating off the inside of the chamber, but, this has met with mixed results. Apparently, other ions are formed during the etching process that can introduce other instabilities and undesired ions into the arc chamber.

Accordingly, although various improvements in the lifetime of an ion implanter source have been achieved, there remains a need to provide an implantation system with an extended implanter source useful lifetime. Improved source lifetime extends the frequency need for servicing the arc chamber and reduces critical down time for the ion implanter unit.

### SUMMARY OF THE INVENTION

Now, according to the present invention, an ion implanter system has been developed having an arc chamber comprising an electron emissive source extending through a wall of the arc chamber, wherein said wall or a substantial portion thereof comprises an insulator material. The source typically may comprise a filament, or cathode, and a repeller or a refractory reflector. The source typically is separated from the wall of the chamber, through which it extends, by insulation, such as an air gap, or a bushing made of high temperature ceramic materials. The provision of an extensive insulator surface surrounding the source, instead of, or in addition to, a standard localized insulation immediately contiguous to the ion source, serves to provide a significantly increased electrical insulating value, thus greatly reducing the occurrence of a short circuit between the source and the chamber wall. The insulator wall comprises a high temperature ceramic material such as alumina, boron nitride, and the like. Boron nitride is a preferred insulator material.

### BRIEF DESCRIPTION OF THE DRAWINGS

FIG. 1 is a perspective view of an arc chamber, including a Freeman source, used for generation of an ion beam for ion implantation.

FIG. 2 is a perspective view of an arc chamber with a Bernas source.

FIG. 3 is a sectional view of an arc chamber including an incandescent heated cathode source.

### DETAILED DESCRIPTION OF PREFERRED EMBODIMENTS

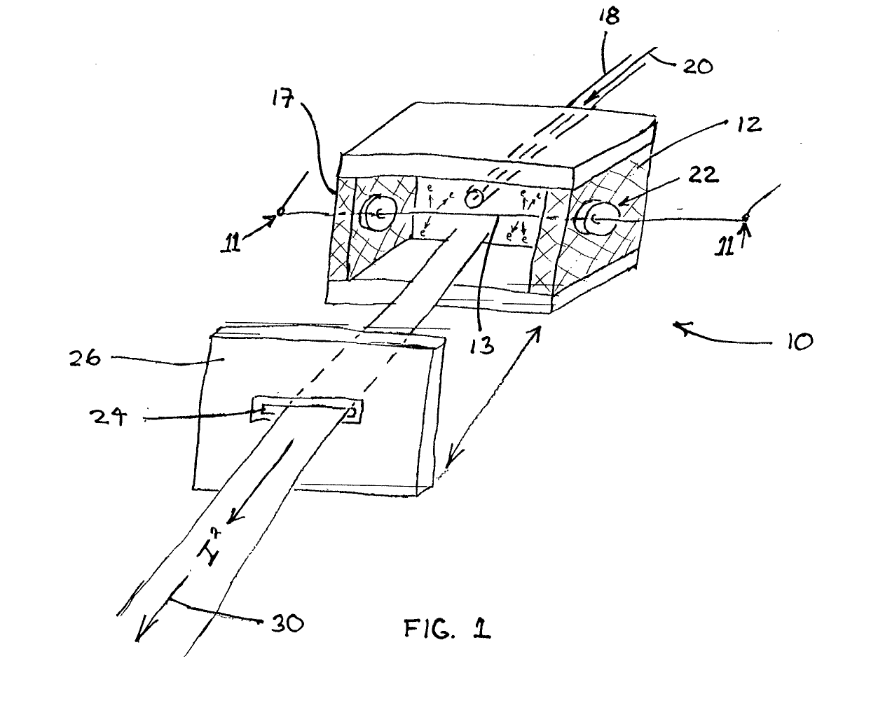

Referring to the FIGURES, as shown in FIG. 1, an ion implanter generally includes an ion implant source arc chamber 10. During operation of the implanter, an ion source gas represented by arrow 20 is introduced into the confines of the source arc chamber 10 through gas feed inlet 18.

The source arc chamber 10 further is equipped with a Freeman filament source 13 extending through walls 12 and 17 of the arc chamber 10 by means of a connector 11 and surrounding insulator bushing 22. A slit 24 is provided in a wall 26 of the chamber 10, through which generated ions, represented by arrow 30 are emitted from the chamber 10.

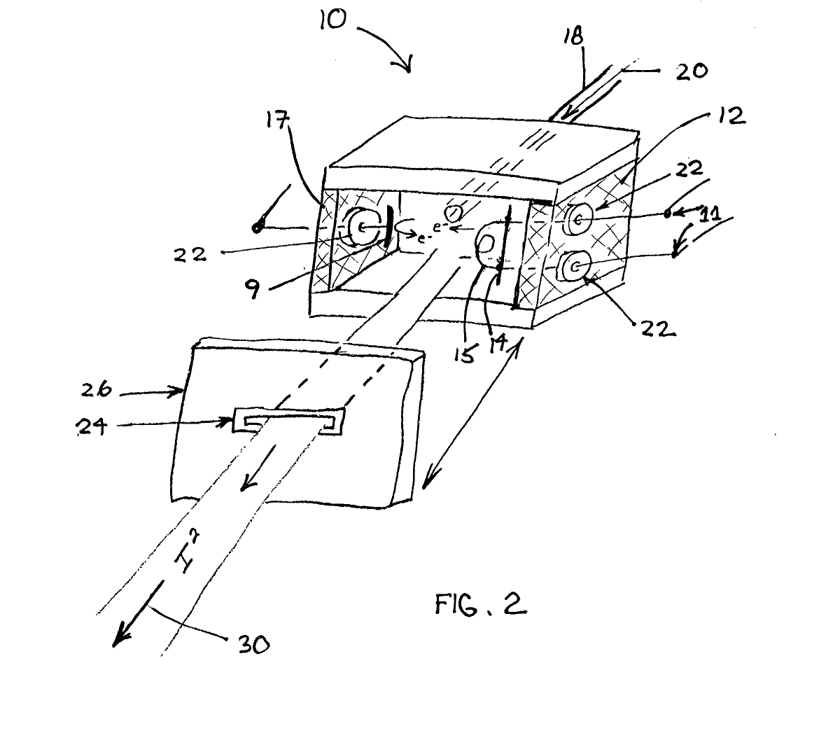

As illustrated in FIG. 2, a coiled filament 15, of the Bernas-type source shown, extends into the interior of the arc source chamber 10 at one end of the chamber and is surrounded by an electron reflector 14, typically made of tungsten or some other suitable refractory material, the reflector 14 serves to reflect the electrons generated in arc chamber 10 away from the filament end of the arc chamber 10. Another refractory reflector 9 is positioned at the opposite end of the chamber 10 from the filament source 15.

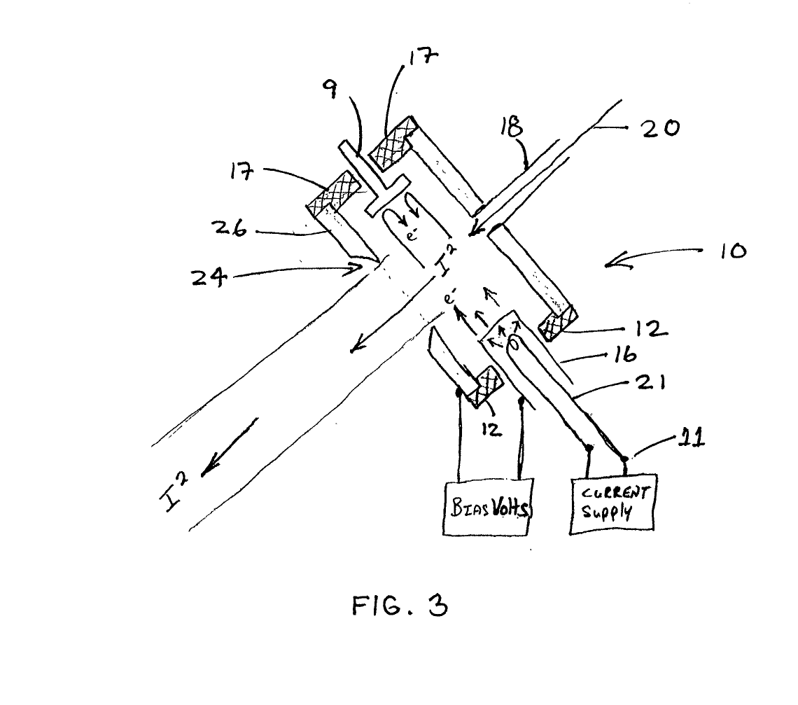

FIG. 3 depicts an arc chamber including a source of the incandescent heated cathode (IHC) type. An incandescent heating element 21 is used to heat cathode element 16, which, in turn, emits electrons.

In order to isolate the source and or reflector from the wall of the arc chamber 10, an insulator bushing 22 commonly is utilized where the source and/or reflector pass through the arc chamber walls. However, even with insulator bushings, deposits on the insulator eventually will cause shorts and source failure.

According to the present invention, the wall 12 and 17 through which the source 13, 15, or 16 and/or reflector 14 extends, is made of an insulator material. The extensive surface of walls 12 and 17 surrounding the arc source and reflector serves to increase significantly the electrical insulating value and reduces the occurrence of short-circuit tendencies.

While preferred embodiments have been shown and described, various modifications and substitutions maybe made thereto without departing from the spirit and scope of the invention. Accordingly, it is to be understood that the present invention has been described by way of illustration and not limitation.

We claim:

1. An arc chamber of an ion implanter system comprising:
an arc chamber enclosure for an electron emissive source, said source extending into said arc chamber enclosure through a wall of said arc chamber enclosure, said wall through which said source extends comprising an insulator material surrounding said source.

2. The arc chamber of claim 1 wherein said insulator material is a high temperature ceramic material.

3. The arc chamber of claim 2 wherein said insulator material is selected from the group consisting of alumina and boron nitride.

4. The arc chamber of claim 3 wherein said insulator material is boron nitride.

5. The arc chamber of claim 1 wherein a substantial portion of said wall through which said source extends into the arc chamber comprises an insulator material.
